(19) United States
(12) Patent Application Publication
(10) Pub. No.: US 2026/0286185 A1
(43) Pub. Date: Sep. 24, 2026

(54) POLISHING COMPOSITION AND POLISHING METHOD

(71) Applicant: FUJIMI INCORPORATED, Kiyosu-shi (JP)

(72) Inventor: Ryota Mae, Kiyosu-shi (JP)

(73) Assignee: FUJIMI INCORPORATED, Kiyosu-shi (JP)

(21) Appl. No.: 19/460,612

(22) Filed: Jan. 27, 2026

(30) Foreign Application Priority Data
Mar. 19, 2025 (JP) 2025-044834

(51) Int. Cl. C09G 1/04; B24B 37/04; C09G 1/02; H10P 52/40

(52) U.S. Cl. CPC C09G 1/04; B24B 37/044; C09G 1/02; H10P 52/403; H10P 52/407

(57) ABSTRACT

The present disclosure provides a polishing composition which allows the polishing removal rate of a material having a silicon-silicon bond to be enhanced and which is also excellent in step height reduction ability on a polishing object including the material having a silicon-silicon bond. The present disclosure relates to a polishing composition including (A) a water-soluble polymer containing a lactam structure and (B) an amine compound, wherein the (B) component has 7 or more and less than 17 carbon atoms and a content mass ratio of the (B) component to the (A) component ((B) component/(A) component) is more than 1.

### TECHNICAL FIELD

The present disclosure relates to a production method of a polishing composition and a polishing method.

### BACKGROUND ART

In general, very fine patterning technologies are used for, for example, manufacturing of semiconductor devices, according to recent miniaturization and densification. Wires constituting semiconductor devices are, for example, multi-layered, thereby more complicating surface structures of semiconductor elements after stacking and also more increasing initial steps in surface films. Flatting technologies utilized for removal of initial steps in specified films formed on substrates are chemical mechanical polishing (CMP) processes. In a case where polishing objects to be polished by CMP have silicon-containing materials, polishing compositions for such silicon-containing materials are applied.

For example, International Publication No. WO2024/171892 discloses a polishing composition to be used for polishing a silicon-containing material.

### SUMMARY OF INVENTION

For example, when a film including a silicon-containing material having a specified initial step is polished to perform polishing of a height portion (thickness X (Å))(where 10 Å=1 nm, the same applies to the following) of the initial step at a polishing removal rate V (Å/min), the step is reducted by polishing for X/V (min) as long as only an upper surface of a protruded portion of the step is selectively polished. However, in practice, a bottom of a depressed portion is also progressively polished at a lower rate than that of the upper portion of the protruded portion of the step, due to chemical etching in a CMP process, deflection of a polishing pad, or the like.

A polishing composition for a silicon-containing material is also demanded to have a step height reduction efficiency closer to 1 (allowing only an upper portion of a protruded portion to be more selectively polished), as an excellent polishing composition. The step height reduction efficiency is here determined as “(the amount (A) of a height portion reducted of a step, by polishing in a certain polishing process (in one depressed portion, the height (A) from the lowest portion of the depressed portion to the uppermost portion of a protruded portion constituting the depressed portion))/(the total amount of polishing in the polishing process (the distance (A) from the height of the uppermost portion of the protruded portion before polishing to the height of the uppermost portion of the protruded portion after polishing))”.

Meanwhile, the polishing composition disclosed in International Publication No. WO2024/171892 is still insufficient in terms of polishing characteristics of a polishing object including a silicon-containing material (for example, material having a silicon-silicon bond), in particular, performance about the step height reduction efficiency, and there is room for improvement from this viewpoint. The polishing removal rate of a material having a silicon-silicon bond is also demanded to be enhanced.

An object of the present disclosure is then to provide a polishing composition which allows the polishing removal rate of a material having a silicon-silicon bond to be enhanced and which is also excellent in step height reduction ability on a polishing object including the material having a silicon-silicon bond.

The inventor of the present disclosure has made intensive studies in order to solve the above problems. As a result, the inventor has found that the above problems are solved by a polishing composition including (A) a water-soluble polymer containing a lactam structure and (B) an amine compound, in which the (B) component has 7 or more and less than 17 carbon atoms and the content mass ratio of the (B) component to the (A) component ((B) component/(A) component) is more than 1, thereby leading to completion of the invention of the present disclosure.

### DESCRIPTION OF EMBODIMENTS

One aspect of the present disclosure is a polishing composition including (A) a water-soluble polymer containing a lactam structure and (B) an amine compound, wherein the (B) component has 7 or more and less than 17 carbon atoms and the content mass ratio of the (B) component to the (A) component ((B) component/(A) component) is more than 1. The polishing composition according to the present disclosure, which has such a configuration, enhances the polishing removal rate of a material having a silicon-silicon bond and also is excellent in step height reduction ability on a polishing object including the material having a silicon-silicon bond. In other words, according to the present disclosure, there is provided a polishing composition which allows the polishing removal rate of a material having a silicon-silicon bond to be enhanced and which is also excellent in step height reduction ability on a polishing object including the material having a silicon-silicon bond.

Hereinafter, embodiments of the present disclosure are described. The present disclosure is not limited only to the following embodiments.

Herein, operations, and measurement of physical properties and the like are performed under conditions of room temperature (20° C. or more and 25° C. or less) and a relative humidity of 40% RH or more and 50% RH or less, unless particularly noted.

Herein, “X or more and Y or less” is used to mean that numerical values (X and Y) described before and after this range are included as the lower limit value and the upper limit value. In a case where a plurality of descriptions “X or more and Y or less” is made, for example, in a case where “X1 or more and Y1 or less, or X2 or more and Y2 or less” is described, all of the disclosure where each numerical value is adopted as the upper limit, the disclosure where each numerical value is adopted as the lower limit, and the disclosure of any combination of such upper limit and lower limit are made (namely, these serve as legitimate bases for amendments). Specifically, all of respective amendments to X1 or more, Y2 or less, X1 or less, Y2 or more, X1 or more and X2 or less, and X1 or more and Y2 or less need to be deemed to be legitimate.

It is to be understood that all combinations of embodiments and descriptions disclosed herein are disclosed in the present application. In other words, it is to be understood that these combinations can serve as bases for amendments.

### [Water-Soluble Polymer Containing Lactam Structure]

The polishing composition according to the present disclosure includes a water-soluble polymer containing a lactam structure (hereinafter, also simply referred to as “(A) component”). The (A) component adsorbs to a surface of a polishing object by hydrogen bonding or hydrophobic interaction, thereby forming a protective film. While this formation of the protective film occurs competitively with peeling of the protective film by polishing, the protective film is hardly peeled on a depressed portion as compared with a protruded portion and therefore it is considered that the polishing removal rate of the depressed portion is kept lower than the polishing removal rate of the protruded portion and the step height reduction ability is enhanced. In other words, it is considered that the (A) component functions as an additive for step height reduction.

Herein, the water-soluble polymer refers to a water-soluble polymer having the same (homopolymer) or different (copolymer) repeating constituent unit, and can be typically a compound having a weight average molecular weight (Mw) of 1000 or more.

The type of the polymer used as the (A) component is not particularly limited, and any of anionic, cationic, nonionic, and amphoteric polymers can be used. In particular, a nonionic water-soluble polymer is preferred because of more easily adsorbing to a polishing object. The (A) component can include a polymer of a monomer having a lactam structure, or a copolymer of a monomer having a lactam structure and any other monomer. Accordingly, according to one aspect of the present disclosure, the water-soluble polymer is a homopolymer of a monomer having a lactam structure, or a copolymer of a monomer having a lactam structure and any other monomer. Examples of such any other monomer can include vinyl alcohol, vinyl acetate, or any other suitable monomer. In a case where the water-soluble polymer is a copolymer, the form of the copolymer may be any of a block copolymer, a random copolymer, a graft copolymer, an alternate copolymer, and a periodic copolymer. The (A) component may be used singly or in combinations of two or more kinds thereof. The (A) component used here may be a synthetic product or a commercially available product.

The (A) component may be at least one selected from the group consisting of polyvinylpyrrolidone, polyvinycaprolactam, polyvinylvalerolactam, polyvinyllaurolactam, and polyvinylpiperidone, and preferably includes polyvinylpyrrolidone.

The weight average molecular weight (Mw) of the (A) component is preferably 1,000 or more, more preferably 3,000 or more, further preferably more than 5,000, particularly preferably 8,000 or more, most preferably 10,000 or more. The weight average molecular weight (Mw) of the (A) component is preferably 1,000,000 or less, more preferably 500,000 or less, further preferably 300,000 or less, particularly preferably 150,000 or less, most preferably less than 150,000. In other words, the weight average molecular weight (Mw) of the (A) component is preferably 1,000 or more and 1,000,000 or less, more preferably 3,000 or more and 100,000 or less, further preferably more than 5,000 and 300,000 or less, particularly preferably 8,000 or more and 150,000 or less, most preferably 10,000 or more and less than 150,000. The weight average molecular weight (Mw) of the (A) component can be measured as a value in terms of polyethylene glycol by use of gel permeation chromatography (GPC). The detail of the measurement method is described in Examples below.

The concentration (content) of the (A) component in the polishing composition is not particularly limited, and is preferably 0.0001% by mass or more, more preferably 0.0003% by mass or more, further preferably 0.0005% by mass or more, still further preferably 0.001% by mass or more, particularly preferably 0.005% by mass or more under the assumption that the total mass of the polishing composition is 100% by mass. The concentration (content) of the (A) component in the polishing composition is not particularly limited, and is preferably 0.3% by mass or less, more preferably 0.2% by mass or less, further preferably 0.1% by mass or less, still further preferably 0.08% by mass or less, particularly preferably 0.06% by mass or less under the assumption that the total mass of the polishing composition is 100% by mass.

In other words, the concentration (content) of the (A) component in the polishing composition is preferably 0.0001% by mass or more and 0.3% by mass or less, more preferably 0.0003% by mass or more and 0.2% by mass or less, further preferably 0.0005% by mass or more and 0.1% by mass or less, still further preferably 0.001% by mass or more and 0.08% by mass or less, particularly preferably 0.005% by mass or more and 0.06% by mass or less under the assumption that the total mass of the polishing composition is 100% by mass.

When the concentration (content) of the (A) component is in such a range, a polishing composition more excellent in step height reduction ability can be obtained. In a case where the polishing composition includes two or more such (A) components, the concentration (content) of the (A) component means the total amount of such (A) components.

### [Amine Compound]

The polishing composition according to the present disclosure includes an amine compound (hereinafter, also simply referred to as “(B) component”). The amine compound has 7 or more and less than 17 carbon atoms. It is considered that the (B) component is added to embrittle a chemical bond (in particular, silicon-silicon bond) contained in a polishing object and enhance the polishing removal rate of such a polishing object (in particular, material containing a silicon-silicon bond).

In a case where an amine compound having less than 7 carbon atoms is used, the step height reduction ability is lowered. In a case where an amine compound having 17 or more carbon atoms is used, the polishing removal rate of a polishing object (in particular, material containing a silicon-silicon bond) is lowered and the step height reduction ability is also lowered.

Herein, the number of carbon atoms means the total number of carbon atoms (namely, the number of carbon atoms, also including the number of carbon atoms in a substituent in the case of this substituent present).

The (B) component may be used singly or in combinations of two or more kinds thereof. The (B) component used here may be a synthetic product or a commercially available product.

Examples of the (B) component include aliphatic amine, aliphatic heterocyclic (alicyclic) amine, aromatic amine, and aromatic heterocyclic amine.

Examples of the aliphatic amine include, n-heptylamine, n-octylamine, di(n-butyl)amine, diisobutylamine, di(sec-butyl)amine, di(tert-butyl)amine, di(n-pentyl)amine, di(n-hexyl)amine, dicyclohexylamine, diisopropylethylamine, 1,7-diaminoheptane, 1,8-diaminooctane, 1,9-diaminononane, 1,10-diaminodecane, and bis(2-ethylhexyl)amine.

Examples of the aliphatic heterocyclic (alicyclic) amine include N-ethylpyrrolidine, N,N′-diethylpiperazine, 1-(2-dimethylaminoethyl)piperazine, 1,4-bis(3-aminopropyl)piperazine (BAPP), N,N′,N″-trimethylaminoethylpiperazine, propylmorpholine, isophoronediamine, N,N′,N″-tris(dimethylaminopropyl)hexahydro-s-triazine, a 3,9-bis(3-aminopropyl)-2,4,8,10-tetraoxyspiro(5,5)undecane adduct, bis(4-aminocyclohexyl)methane, 1,8-diazabicyclo-[5.4.0]-undec-7-ene (DBU), 1,5-diazabicyclo[4.3.0]non-5-ene (DBN), and quinuclidine.

Examples of the aromatic amine include methylaniline and N,N-dimethylaniline.

Examples of the aromatic heterocyclic amine include a compound having 7 or more and less than 17 carbon atoms, among a pyrrole compound, an imidazole compound, a benzimidazole compound, a pyrazole compound, an oxazole compound, an isoxazole compound, a thiazole compound, an isothiazole compound, a melamine compound, a pyridine compound, a pyrimidine compound, a pyridazine compound, a pyrazine compound, a triazine compound, a quinoline compound, an isoquinoline compound, a quinazoline compound, a phthalazine compound, and an indole compound.

Among such (B) components, the (B) component is preferably at least one of an aliphatic amine and an aliphatic heterocyclic (alicyclic) amine, more preferably has a cyclic structure, and is further preferably at least one of 1,4-bis(3-aminopropyl)piperazine (BAPP) and 1,8-diazabicyclo[5.4.0]undeca-7-ene (DBU). It is considered that such a (B) component can more promote embrittlement of a silicon-silicon bond contained in a polishing object and more enhance the polishing removal rate of a polishing object including a material containing a silicon-silicon bond. In one embodiment, it is preferable not to include any amine compound other than the (A) component and the (B) component.

In one embodiment of the present disclosure, the number of carbon atoms contained in the (B) component is preferably 8 or more and 16 or less, more preferably 9 or more and 12 or less.

The molecular weight of the (B) component is not particularly limited, and is usually less than 1000. Herein, the molecular weight is the sum of the atomic weights of atoms constituting such an ion or compound.

The concentration (content) of the (B) component in the polishing composition is not particularly limited, and is preferably 0.005% by mass or more, more preferably 0.008% by mass or more, further preferably 0.01% by mass or more, particularly preferably 0.02% by mass or more under the assumption that the total mass of the polishing composition is 100% by mass. The concentration (content) of the (B) component in the polishing composition is not particularly limited, and is preferably 3% by mass or less, more preferably 2% by mass or less, further preferably 1% by mass or less, particularly preferably 0.6% by mass or less under the assumption that the total mass of the polishing composition is 100% by mass.

In other words, the concentration (content) of the (B) component in the polishing composition is preferably 0.005% by mass or more and 3% by mass or less, more preferably 0.008% by mass or more and 2% by mass or less, further preferably 0.01% by mass or more and 1% by mass or less, particularly preferably 0.02% by mass or more and 0.6% by mass or less under the assumption that the total mass of the polishing composition is 100% by mass.

When the concentration (content) of the (B) component is in this range, a polishing composition which is more excellent in step height reduction ability and which can enhance the polishing removal rate of a material having a silicon-silicon bond. In a case where the polishing composition includes two or more such (B) components, the concentration (content) of the (B) component means the total amount of such components.

### [Content Mass Ratio of (B) Component to (A) Component ((B) Component/(A) Component)]

The content mass ratio of the (B) component to the (A) component ((B) component/(A) component) in the polishing composition according to the present disclosure is more than 1. In a case where the content mass ratio is 1 or less, the step height reduction ability, and the polishing removal rate of a material having a silicon-silicon bond are lowered. The content mass ratio of the (B) component to the (A) component ((B) component/(A) component) in the polishing composition is preferably 2 or more, more preferably 5 or more, further preferably 7 or more. The content mass ratio of the (B) component to the (A) component ((B) component/(A) component) is preferably 200 or less, more preferably 100 or less, further preferably 70 or less, still further preferably 50 or less, particularly preferably 20 or less.

In other words, the content mass ratio of the (B) component to the (A) component ((B) component/(A) component) in the polishing composition is preferably 2 or more and 200 or less, more preferably 5 or more and 100 or less, further preferably 5 or more and 70 or less, still further preferably 7 or more and 50 or less, particularly preferably 7 or more and 20 or less.

In a case where the polishing composition includes two or more such (A) components, the content of the (A) component means the total amount of such components. Similarly, in a case where the polishing composition includes two or more such (B) components, the content of the (B) component means the total amount of such components.

### [Electrical Conductivity of Polishing Composition]

The electrical conductivity (EC) of the polishing composition according to the present disclosure is not particularly limited, and is preferably 0.5 mS/cm or more and 20 mS/cm or less, more preferably 0.8 mS/cm or more and 15 mS/cm or less, further preferably 1 mS/cm or more and 10 mS/cm or less.

The electrical conductivity of the polishing composition can be adjusted depending on the type and the concentration of the (B) component, and the type, the concentration, and the like of a pH adjusting agent described later. The electrical conductivity of the polishing composition can be measured by a method described in Examples.

The polishing composition according to the present disclosure may further include an electrical conductivity adjusting agent for adjusting the electrical conductivity. The electrical conductivity adjusting agent is not particularly limited as long as it is any other component than the (B) component and the pH adjusting agent and has a function of adjusting the electrical conductivity, and examples thereof include a salt compound.

### [Abrasive Grain]

The polishing composition according to the present disclosure may include an abrasive grain.

The abrasive grain is not particularly limited, and may be any of an inorganic particle and an organic particle. The inorganic particle is not particularly limited, and examples include each particle including a metal oxide such as silica, alumina, ceria, or titania. The organic particle is not particularly limited, and examples include a polymethyl methacrylate (PMMA) particle. In particular, the abrasive grain is preferably silica (silica abrasive grain), or colloidal silica (colloidal silica abrasive grain).

The shape of the abrasive grain is not particularly limited, and may be a spherical shape or a non-spherical shape. Specific examples of the non-spherical shape include various shapes, for example, polygonal columns such as a triangular column and a quadrangular column, a cylindrical shape, a bale shape in which the central portion of a cylinder is bulged as compared with an end portion, a donut shape in which the central portion of a disc penetrates, a plate-like shape, a so-called cocoon-like shape having a constriction at the central portion, a so-called associated spherical shape in which plural particles are integrated, a beaded shape in which plural particles are joined substantially in line, a so-called “konpeito” shape having plural protrusions on the surface, a rugby ball shape, and a needle-like shape finer than a rugby ball shape, but are not particularly limited thereto. In particular, a cocoon-like shape is preferred.

The average primary particle size of the abrasive grain is not particularly limited, and is preferably 5 nm or more, more preferably 7 nm or more, further preferably 10 nm or more, still further preferably 25 nm or more, particularly preferably 30 nm or more. In a case where the average primary particle size is in this range, the polishing removal rate is more enhanced. The average primary particle size of the abrasive grain is not particularly limited, and is preferably 120 nm or less, more preferably 80 nm or less, further preferably 50 nm or less, particularly preferably 40 nm or less. The average primary particle size of the abrasive grain can be calculated from the specific surface area of the abrasive grain, determined by a BET (Brunauer-Emmett-Teller) method.

The average secondary particle size of the abrasive grain is not particularly limited, and is preferably 10 nm or more, more preferably 20 nm or more, further preferably 30 nm or more, particularly preferably 50 nm or more. The average secondary particle size of the abrasive grain is not particularly limited, and is preferably 250 nm or less, more preferably 200 nm or less, further preferably 150 nm or less, particularly preferably 100 nm or less. The value of the average secondary particle size of the abrasive grain can be measured by a dynamic light scattering method.

The abrasive grain may be used singly or in combinations of two or more kinds thereof. The abrasive grain used here may be a synthetic product or a commercially available product.

However, the concentration (content) of the abrasive grain is preferably 0.5% by mass or less based on the total mass of the polishing composition from the viewpoint that the polishing removal rate of a material containing a silicon-nitrogen bond, used as a stop film, is suppressed as much as possible. The concentration (content) of the abrasive grain is more preferably less than 0.5% by mass, further preferably 0.3% by mass or less, particularly preferably 0.1% by mass or less. The most preferred mode is a mode in which the concentration (content) of the abrasive grain is 0% by mass, namely, the abrasive grain is not included in the polishing composition at all. Here, in a case where the abrasive grain is included in the polishing composition, the lower limit value of the concentration (content) of the abrasive grain is more than 0% by mass.

### [pH and pH Adjusting Agent]

The pH of the polishing composition according to the present disclosure is not particularly limited, and is preferably 8 or more and 12 or less. The pH is more preferably 8.5 or more, further preferably 9 or more. The pH is more preferably 12 or less, further preferably 11.5 or less, further preferably 11 or less. In other words, the pH of the polishing composition according to the present disclosure is preferably 8 or more and 12 or less, more preferably 8.5 or more and 11.5 or less, further preferably 9 or more and 11 or less.

The (A) component and the (B) component in the present disclosure can each serve as a pH adjusting agent. Here, if the above desired pH is not obtained by only the (A) component and the (B) component, the polishing composition according to the present disclosure may further include a pH adjusting agent other than the (A) component and the (B) component. This pH adjusting agent is not particularly limited, a known pH adjusting agent can be used, or a known acid, base, or any salt thereof can be used. Examples of this pH adjusting agent include organic acids, for example, carboxylic acids such as formic acid, acetic acid, glycolic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic-acid, linolenic acid, arachidonic acid, docosahexaenoic acid, eicosapentaenoic acid, lactic acid, malic acid, tartaric acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acid and anthranilic acid, sulfonic acids (isethionic acid, camphorsulfonic acid, and the like), and organic phosphonic acids (hydroxyethylidenediphosphonic acid, and diethylenetriaminepentamethylenephosphonic acid, and the like); inorganic acids such as nitric acid, carbonic acid, hydrochloric acid, sulfuric acid, phosphoric acid, hypophosphorous acid, phosphorus acid, phosphonic acid, boric acid, hydrofluoric acid, orthophosphoric acid, pyrophosphoric acid, metaphosphoric acid, and hexametaphosphoric acid; hydroxides of alkali metals, such as potassium hydroxide (KOH) and sodium hydroxide (NaOH); carbonates of alkali metals, such as potassium carbonate (K₂CO₃) and sodium carbonate (Na₂CO₃); hydroxides of alkali earth metals, ammonia (ammonium hydroxide); and organic bases such as a quaternary ammonium hydroxide compound.

Such a pH adjusting agent may be used singly or in combinations of two or more kinds thereof. Such a pH adjusting agent used here may be a synthetic product or a commercially available product.

The pH of the polishing composition can be measured with, for example, a pH meter, and specifically can be measured by a method described in Examples.

### [Dispersing Medium]

The polishing composition according to the present disclosure preferably includes a dispersing medium for dispersing each component. Examples of the dispersing medium can include water; alcohols such as methanol, ethanol, and ethylene glycol; ketones such as acetone, and any mixture thereof. In particular, the dispersing medium is preferably water. In other words, according to a preferred aspect of the present disclosure, the dispersing medium includes water. According to a more preferred aspect of the present disclosure, the dispersing medium substantially includes water. Herein, the “substantially” means that any other dispersing medium than water can be included as long as the effects of the present disclosure are achieved. More specifically, the dispersing medium preferably includes 90% by mass or more and 100% by mass or less of water and 0% by mass or more and 10% by mass or less of any other dispersing medium than water, more preferably includes 99% by mass or more and 100% by mass or less of water and 0% c by mass or more and 1% by mass or less of any other dispersing medium than water. The dispersing medium is most preferably water.

The dispersing medium is preferably water not containing impurities as much as possible from the viewpoint of not inhibiting the effects of the components included in the polishing composition. Specifically, the dispersing medium is more preferably pure water or ultrapure water obtained by removing impurity ions with an ion exchange resin and then removing foreign substances through a filter, or distilled water.

### [Other Components]

The polishing composition according to the present disclosure may further contain any known additive usable for polishing compositions, such as a complexing agent, an antiseptic agent, a surfactant, an antifungal agent, and/or an oxidizing agent as long as the effects of the present disclosure are not impaired. The polishing composition according to the present disclosure more preferably contain an antifungal agent. In other words, in one embodiment of the present disclosure, the polishing composition is substantially constituted from (A) the water-soluble polymer containing a lactam structure, (B) the amine compound, the dispersing medium, and at least one of the pH adjusting agent and an antifungal agent. In one embodiment of the present disclosure, the polishing composition is substantially constituted from (A) the water-soluble polymer containing a lactam structure, (B) the amine compound, the dispersing medium, and the pH adjusting agent. Herein, the “polishing composition is substantially constituted from (A) the water-soluble polymer containing a lactam structure, (B) the amine compound, the dispersing medium, and at least one of the pH adjusting agent and an antifungal agent” means that the total content of (A) the water-soluble polymer containing a lactam structure, (B) the amine compound, the dispersing medium, the pH adjusting agent, and the antifungal agent is more than 99% by mass (upper limit.100% by mass) based on the total mass of the polishing composition. The polishing composition is preferably constituted from (A) the water-soluble polymer containing a lactam structure, (B) the amine compound, the dispersing medium, and the pH adjusting agent (the total content=100% by mass).

Examples of the antifungal agent (antiseptic agent) which can be added to the polishing composition according to the present disclosure include 1,2-benzoisothiazol-3(2H)-one (BIT); isothiazoline-based antiseptic agents such as 2-methyl-4-isothiazolin-3-one and 5-chloro-2-methyl-4-isothiazolin-3-one; paraoxybenzoates; and phenoxyethanol. Such an antifungal agent may be used singly or in combinations of two or more kinds thereof.

### [Method for Producing Polishing Composition]

The method for producing the polishing composition according to the present disclosure is not particularly limited, and the polishing composition can be obtained by, for example, stirring and mixing the (A) component, the (B) component, and, if necessary, any other additive in the dispersing medium (for example, water) The detail of each of the components is as described above.

The temperature during mixing of each of the components is not particularly limited, and is preferably 10° C. or more and 40° C. or less, and heating may also be performed for increasing the rate of dissolution. The mixing time is also not particularly limited as long as uniform mixing can be made.

### [Polishing Object]

A polishing composition according to one embodiment of the present disclosure can be applied to a known polishing object which is not particularly limited and which is used in the CMP field. Therefore, an aspect of the polishing object is not particularly limited, a layer being a flat-plate-like member is preferred, a substrate including the layer is more preferred, and a semiconductor substrate is further preferred. Examples include a substrate constituted from a single layer, and a substrate including a layer to be polished and any other layer (for example, a support layer or any other functional layer). Examples of the material constituting the polishing object include, but not particularly limited thereto, a silicon-containing material and a metal-containing material (for example, a metal simple substance, metal oxide, and metal nitride). The material constituting the polishing object may be adopted singly or in combinations of two or more kinds thereof.

Examples of the silicon-containing material include, but not particularly limited thereto, a material having a silicon-oxygen bond, a material having a silicon-silicon bond, and a material having a silicon-nitrogen bond. Examples of the material having a silicon-oxygen bond include, but not particularly limited thereto, silicon oxide, BD (black diamond: SiOCH), FSG (fluorosilicate glass), HSQ (hydrogen silsesquioxane), CYCLOTENE, SiLK, and MSQ (Methyl silsesquioxane). Examples of the polishing object having a silicon-silicon bond include, but not particularly limited thereto, polycrystalline silicon (polysilicon, Poly-Si), amorphous silicon (a-Si), monocrystalline silicon, n-type doped monocrystalline silicon, and p-type doped monocrystalline silicon, and Si-type alloys such as SiGe. Examples of the material having a silicon-nitrogen bond include, but not particularly limited thereto, silicon nitride and silicon carbonitride (SiCN).

Among such silicon-containing materials, the polishing object is preferably the material having a silicon-silicon bond, more preferably amorphous silicon. The polishing object preferably includes not only the material having a silicon-silicon bond, but also the material having a silicon-nitrogen bond. A film including the material having a silicon-nitrogen bond can be used as a stop film.

### [Polishing Method]

As described above, the polishing composition according to the present disclosure is suitably used for polishing a polishing object containing a material having a silicon-silicon bond. Accordingly, one aspect of the present disclosure relates to a polishing method including a step of polishing a polishing object containing a material having a silicon-silicon bond with the polishing composition according to the present disclosure. One aspect of the present disclosure relates to a method for producing a substrate, the method including polishing a polishing object containing a material having a silicon-silicon bond by the polishing method according to the present disclosure.

The polishing apparatus used here can be a common polishing apparatus which is equipped with a holder for retaining a substrate or the like having a polishing object and a motor changeable in number of rotations, and the like, and which has a polishing table to which a polishing pad (polishing cloth) can be attached.

The type of the polishing pad used in each of the polishing method and the method for producing a semiconductor substrate, according to the present disclosure, is not particularly limited, and can be, for example, an expanded polyurethane type, a non-woven cloth type, or a suede type.

The shore D hardness of the polishing pad is preferably 30 or more. When the shore D hardness is 30 or more, the pressure applicable to a polishing object can be increased and the polishing removal rate is more enhanced. The shore D hardness of the polishing pad is more preferably 40 or more, further preferably 50 or more. The shore D hardness of the polishing pad is preferably 90 or less, more preferably 80 or less, further preferably 70 or less. When the shore D hardness is 90 or less, the polishing pad can well follow a polishing object surface during polishing and polishing can be stably performed. The shore D hardness can be measured by a method described in JIS K 7215:1986.

Among polishing conditions, for example, the rotational speed of a polishing table is, for example, preferably 10 rpm (0.17 s⁻¹; 60 rpm=1 s⁻¹, the same applies to the following) or more and 500 rpm (8.33 s⁻¹). The pressure (polishing pressure) applied to a substrate having a polishing object is preferably 0.5 psi (3.4 kPa; 1 psi=6894.76 Pa, the same applies to the following) or more and 10 psi (68.9 kPa). The method for supplying the polishing composition to the polishing pad is also not particularly limited, and, for example, a continuously supplying method with a pump or the like is adopted. The amount of this supplying is not limited, and a surface of the polishing pad is preferably always covered with the polishing composition according to the present disclosure.

After completion of polishing, a substrate is washed in flowing water and water droplets attached onto the substrate are blown away with a spin dryer or the like, thereby providing a substrate containing a material having a silicon-silicon bond.

The polishing composition according to the present disclosure may be of one-liquid-type, or of multi-liquid type including two-liquid type. The polishing composition according to the present disclosure may also be prepared by diluting a stock solution of the polishing composition with a dilution liquid such as water to, for example, two times or more and 10 times or less.

A polishing composition according to more preferred one aspect of the present disclosure is suitably used for polishing a polishing object having a material having a silicon-silicon bond, in which the material is embedded on a substrate having a depressed portion so as to cover the depressed portion. In other words, the present disclosure also provides a polishing method including polishing a material having a silicon-silicon bond, in which the material is embedded on a substrate having a depressed portion so as to cover the depressed portion, with the polishing composition of the present disclosure.

Specific examples of the material having a silicon-silicon bond, in which the material is embedded on a substrate having a depressed portion so as to cover the depressed portion, include the above material having a silicon-silicon bond, more preferably include amorphous silicon. Here, a stop film may be formed between a film including the material having a silicon-silicon bond and the substrate. Examples of the material of such a stop film include a material having a silicon-nitrogen bond, preferably include silicon nitride.

### [Step Height Reduction Ability]

A polishing method with a polishing composition according to preferred one embodiment of the present disclosure includes polishing a surface of a polishing object containing a material having a silicon-silicon bond, with the polishing composition. Thus, polishing characteristics of the polishing object can be more enhanced. In particular, in a case where a step due to multi-layering of wires, or the like, for example, an initial step is generated on a surface of a substrate, the step height reduction ability can be enhanced. This step height reduction ability can be evaluated with the step height reduction efficiency determined as “(the amount (A) of a height portion reducted of a step, by polishing in a certain polishing process (in one depressed portion, the height (Å) from the lowest portion of the depressed portion to the uppermost portion of a protruded portion constituting the depressed portion)) (the amount of step height reduction) (A)/(the total amount of polishing in the polishing process (the distance (A) from the height of the uppermost portion of the protruded portion before polishing to the height of the uppermost portion of the protruded portion after polishing))”. As such a value is closer to 1, only an upper surface of the protruded portion can be selectively polished to make the polishing efficiency more excellent. The step height reduction efficiency is preferably 0.15 (15%) or more, more preferably 0.3 (30%) or more, further preferably 0.4 (40%) or more, particularly preferably more than 0.4 (40%) (upper limit 1 (100%)) in the case of polishing in polishing conditions of, for example, a polishing pressure of 2.5 psi (17.2 kPa) and a number of polishing table rotations of 90 rpm (1.5 s¹).

### [Polishing Removal Rate]

The polishing composition according to the present disclosure can enhance the polishing removal rate of particularly a polishing object containing a material having a silicon-silicon bond.

In a case where polishing is performed with the polishing composition according to the present disclosure, the polishing removal rate of the material having a silicon-silicon bond may be preferably 1500 Å/min or more, 1600 Å/min or more, 1700 Å/min or more, 1800 Å/min or more, 1900 Å/min or more, or 2000 Å/min or more.

Although embodiments of the present disclosure are described in detail, it is clear that these embodiments are descriptive and illustrative and are not limiting and the scope of the present disclosure is to be interpreted by the accompanying claims.

The present disclosure encompasses the following aspects and modes:
[1] A polishing composition comprising
(A) a water-soluble polymer containing a lactam structure, and
(B) an amine compound, wherein
the (B) component has 7 or more and less than 17 carbon atoms, and
a content mass ratio of the (B) component to the (A) component ((B) component/(A) component) is more than 1:
[2] The polishing composition according to [1], wherein the (A) component is at least one selected from the group consisting of polyvinylpyrrolidone, polyvinycaprolactam, polyvinylvalerolactam, polyvinyllaurolactam, and polyvinylpiperidone
[3] The polishing composition according to [1] or [2], wherein the (B) component has a cyclic structure:
[4] The polishing composition according to [3], wherein the (B) component is at least one of 1,4-bis(3-aminopropyl)piperazine (BAPP) and 1,8-diazabicyclo[5.4.0]undeca-7-ene (DBU):
[5] The polishing composition according to any of [1] to [4], further comprising a dispersing medium:
[6] The polishing composition according to any of [1] to [5], wherein a pH is 8 or more and 12 or less.
[7] The polishing composition according to any of [1] to [6], wherein a content of an abrasive grain based on a total mass of the polishing composition is less than 0.5% by mass:
[8] The polishing composition according to any of [1] to [7], for use in the polishing of a polishing object containing a material having a silicon-silicon bond:
[9] The polishing composition according to [8], wherein the material having a silicon-silicon bond is amorphous silicon:
[10] The polishing composition according to [8] or [9], wherein the polishing object further contains a material having a silicon-nitrogen bond:
[11]A polishing method comprising polishing a material having a silicon-silicon bond, in which the material is embedded on a substrate having a depressed portion so as to cover the depressed portion, with the polishing composition according to any of [1] to [10].

### EXAMPLES

The present disclosure is described in further detail with reference to the following Examples and Comparative Examples. However, the technical scope of the present disclosure is not limited to only the following Examples. Unless particularly noted, “%” and “part(s)” respectively mean “% by mass” and “part(s) by mass”.

### <Weight Average Molecular Weight of (A) Component>

The weight average molecular weight of the (A) component was measured by gel permeation chromatography (GPC) with polyethylene glycol as a standard substance. Detailed conditions are as described below:
GPC apparatus: manufactured by Shimadzu Corporation
Model: Prominence
Column: Shim-pack (registered trademark) VP-ODS (manufactured by Shimadzu GLC Ltd.)
Mobile phase A. MeOH
Mobile phase B: aqueous 1% acetic acid solution
Flow rate: 1 mL/min
Detector: ELSD (Evaporative Light Scattering Detector) Detector (ELSD-LTII) temp. 40° C., Gain 8, N₂ GAS 350 kPa
Oven temperature: 40° C.
Amount of injection: 40 μl.

### <pH of Polishing Composition>

The pH of the polishing composition was measured as a value at 25° C. with a pH meter (Model number: LAQUA (registered trademark) manufactured by Horiba Ltd.).

### <Electrical Conductivity of Polishing Composition>

The electrical conductivity (EC) of the polishing composition was measured with a desktop-type electrical conductivity meter (Model number: DS-71 manufactured by Horiba Ltd.).

### <Components of Polishing Composition>

The detail of the (A) component used for preparation of the polishing composition is as described below:
PVP: polyvinylpyrrolidone, Mw: 45,000.

The detail of a water-soluble polymer (in Table 1, designated as “(A′) component”) other than the (A) component is as described below:
PVA: polyvinyl alcohol, Mw: 10,000.
PA: polyacrylic acid, Mw: 200,000.

### <Polishing Object>

A polishing object used for evaluation of the polishing removal rate (polishing object for polishing removal rate evaluation), prepared here, was each of a silicon wafer (a-Si substrate, diameter 300 mm) where an amorphous silicon film having a thickness of 2000 Å was formed on a surface of the wafer by chemical vapor deposition (CVD) and a silicon wafer (SiN substrate, diameter 300 mm) where a SiN film having a thickness of 2500 Å was formed on a surface of the wafer.

A polishing object used for evaluation of the step height reduction ability (polishing object for step height reduction ability evaluation), used here, was a silicon wafer where an amorphous silicon film having a thickness of 3000 Å and an initial step of 800 Å was formed on a surface of the wafer.

### Example 1

To 0.1 g of polyvinylpyrrolidone (PVP) as the (A) component, 300 g of ultrapure water was added and the resultant was stirred. Next, 1.0 g of 1,4-bis(3-aminoethyl)piperazine (BAPP) as the (B) component and 300 g of ultrapure water were added. Furthermore, nitric acid as the pH adjusting agent was added in an amount so that the final pH of the polishing composition was 10.5, and ultrapure water was added so that the total mass of the polishing composition was 1 kg, thereby preparing polishing composition 1.

### Example 2

To 0.1 g of polyvinylpyrrolidone (PVP) as the (A) component, 300 g of ultrapure water was added and the resultant was stirred. Next, 0.2 g of 1,4-bis(3-aminoethyl)piperazine (BAPP) as the (B) component and 300 g of ultrapure water were added. Furthermore, nitric acid as the pH adjusting agent was added in an amount so that the final pH of the polishing composition was 10.5, and ultrapure water was added so that the total mass of the polishing composition was 1 kg, thereby preparing polishing composition 2.

### Example 3

To 0.1 g of polyvinylpyrrolidone (PVP) as the (A) component, 300 g of ultrapure water was added and the resultant was stirred. Next, 1.0 g of 1,8-diazabicyclo[5.4.0]undeca-7-ene (DBU) as the (B) component and 300 g of ultrapure water were added. Furthermore, nitric acid as the pH adjusting agent was added in an amount so that the final pH of the polishing composition was 10.5, and ultrapure water was added so that the total mass of the polishing composition was 1 kg, thereby preparing polishing composition 3.

### Example 4

To 0.1 g of polyvinylpyrrolidone (PVP) as the (A) component, 300 g of ultrapure water was added and the resultant was stirred. Next, 1.0 g of n-heptylamine as the (B) component and 300 g of ultrapure water were added. Furthermore, nitric acid as the pH adjusting agent was added in an amount so that the final pH of the polishing composition was 10.5, and ultrapure water was added so that the total mass of the polishing composition was 1 kg, thereby preparing polishing composition 4.

### Example 5

Polishing composition 5 was prepared in the same manner as in Example 4 except that 1.0 g of bis(2-ethylhexyl)amine was added instead of 1.0 g of n-heptylamine.

### Comparative Example 1

Polishing composition comparison 1 was prepared in the same manner as in Example 3 except that 1.0 g of N-(2-aminoethyl)piperazine was added instead of 1.0 g of 1,8-diazabicyclo[5.4.0]undeca-7-ene (DBU).

### Comparative Example 2

Polishing composition comparison 2 was prepared in the same manner as in Example 3 except that 1.0 g of trihexylamine was added instead of 1.0 g of 1,8-diazabicyclo[5.4.0]undeca-7-ene (DBU).

### Comparative Example 3

To 0.6 g of polyvinyl alcohol (PVA) as the (A′) component, 300 g of ultrapure water was added and 0.1 g of polyacrylic acid (PA), and the resultant was stirred. Next, 1.0 g of N-(2-aminoethyl)piperazine as the (B) component and 300 g of ultrapure water were added. Furthermore, nitric acid as the pH adjusting agent was added in an amount so that the final pH of the polishing composition was 10.0, and ultrapure water was added so that the total mass of the polishing composition was 1 kg, thereby preparing polishing composition comparison 3.

### Comparative Example 4

To 0.1 g of polyvinylpyrrolidone (PVP) as the (A) component, 300 g of ultrapure water was added and the resultant was stirred. Next, 0.1 g of 1,4-bis(3-aminoethyl)piperazine (BAPP) as the (B) component and 300 g of ultrapure water were added. Furthermore, ammonia as the pH adjusting agent was added in an amount so that the final pH of the polishing composition was 10.5, and ultrapure water was added so that the total mass of the polishing composition was 1 kg, thereby preparing polishing composition comparison 4.

### [Polishing Conditions]

Each of the polishing compositions of Examples and Comparative Examples obtained as described above was used to polish a polishing object for polishing removal rate evaluation in the following polishing conditions:
Polishing apparatus: F-REX 300E manufactured by Ebara Corporation
Polishing pad: IK4250H (shore D hardness: 60) manufactured by Du Pont
Polishing time: 20 seconds
Pressure of polishing table pressure: 2.5 psi (17.2 kPa)
Number of rotations of polishing table: 60 rpm
Number of rotations of carrier: 63 rpm
Supply rate of polishing composition: 200 ml/min

### [Measurement of Polishing Removal Rate]

The polishing removal rate (polishing rate) of the polishing object was calculated by the following expression.

$$Polishing removal rate [ Å / min ] = ( Thickness [ Å ] before polishing - Thickness [ Å ] after polishing ) / Poishing time [ min ] \qquad [ Expression 1 ]$$

The thicknesses before and after polishing of the polishing object were determined with a light interference type film thickness measurement apparatus (Model number: A-SET F5X manufactured by KLA-Tencor), and the difference therebetween was divided by the polishing time to calculate the polishing removal rate.

### [Step Height Reduction Ability (Step Height Reduction Efficiency)]

The above-prepared polishing object for step height reduction ability evaluation was cut to a size of 60 mm×60 mm, and a surface thereof was polished by only 1000 Å in the following polishing conditions. The value of the step height reduction efficiency was obtained as the value by dividing the amount of step height reduction, as determined by subtracting the step after polishing from the initial step, (initial step—step after polishing), by the amount of polishing (1000 Å), as expressed in terms of percentage (see the following expression). The step was measured with an atomic force microscope (AFM, manufactured by Bruker, Dimention ICON). The step height reduction efficiency is more preferably closer to a numerical value of 100%:
Polishing apparatus: desktop polishing machine EJ-3801N manufactured by ENGIS JAPAN Corporation
Polishing pad: IK4250H (shore D hardness:60) manufactured by Du Pont
Pressure of polishing table: 2.5 psi (17.2 kPa)
Number of rotations of polishing table: 90 rpm
Supply rate of polishing composition: 20 ml/min.

$$Step height reduction efficiency ( \% ) = ( Amount of step reduction / Amount of polishing ) \times 100 \qquad [ Expression 2 ]$$

The constitutions of the polishing compositions of Examples and Comparative Examples are shown in Table 1 below, and the results of each evaluation described above are shown in Table

TABLE 1

| | | | | | (B) Component | | | | | | |
|---|---|---|---|---|---|---|---|---|---|---|---|
| | | (A) Component/(A′) | | | | | Number | | | | |
| | | Component | | | | | of | Content | | | |
| | | | | Concen- | | Concen- | carbon | mass ratio | | | |
| | | | | tration | | tration | atoms | of (B) | pH | | EC |
| | Composition | | | (% by | | (% by | in | Component/(A) | adjusting | | (mS/c |
| | No. | Type | Mw | mass) | Type | mass) | molecule | Component | agent | pH | m) |
| Example | 1 | PVP | 45,000 | 0.01 | BAPP | 0.1 | 10 | 10 | HNO₃ | 10.5 | 1.5 |
| 1 | | | | | | | | | | | |
| Example | 2 | PVP | 45,000 | 0.01 | BAPP | 0.02 | 10 | 2 | HNO₃ | 10.5 | 1.5 |
| 2 | | | | | | | | | | | |
| Example | 3 | PVP | 45,000 | 0.01 | DBU | 0.1 | 9 | 10 | HNO₃ | 10.5 | 1.8 |
| 3 | | | | | | | | | | | |
| Example | 4 | PVP | 45,000 | 0.01 | n-Heptylamine | 0.1 | 7 | 10 | HNO₃ | 10.5 | 1.0 |
| 4 | | | | | | | | | | | |
| Example | 5 | PVP | 45,000 | 0.01 | Bis(2- | 0.1 | 16 | 10 | HNO₃ | 10.5 | 1.3 |
| 5 | | | | | ethylhexyl)amine | | | | | | |
| Comparative | Comparison 1 | PVP | 45,000 | 0.01 | N-(2- | 0.1 | 6 | 10 | HNO₃ | 10.5 | 1.8 |
| Example | | | | | Aminoethyl)piper- | | | | | | |
| 1 | | | | | azine | | | | | | |
| Comparative | Comparison 2 | PVP | 45,000 | 0.01 | Trihexylamine | 0.1 | 18 | 10 | HNO₃ | 10.5 | 1.4 |
| Example | | | | | | | | | | | |
| 2 | | | | | | | | | | | |
| Comparative | Comparison 3 | PVAPA | 10,000 | 0.06 | N-(2- | 0.1 | 6 | — | HNO₃ | 10.0 | 2.0 |
| Example | | | 200,000 | 0.01 | Aminoethyl)piper- | | | | | | |
| 3 | | | | | azine | | | | | | |
| Comparative | Comparison 4 | PVP | 45,000 | 0.01 | BAPP | 0.01 | 10 | 1.0 | NH₃ | 10.5 | 1.8 |
| Example | | | | | | | | | | | |
| 4 | | | | | | | | | | | |

TABLE 2

| | | Polishing removal | | Step height |
|---|---|---|---|---|
| | Composition | rate (Å/min) | | reduction efficiency |
| | No. | a-Si | SiN | (%) |
| Example 1 | 1 | 2650 | 0 | 49 |
| Example 2 | 2 | 1988 | 0 | 43 |
| Example 3 | 3 | 2023 | 0 | 47 |
| Example 4 | 4 | 1950 | 0 | 45 |
| Example 5 | 5 | 1862 | 0 | 49 |
| Comparative | Comparison 1 | 2300 | 0 | 40 |
| Example 1 | | | | |
| Comparative | Comparison 2 | 1654 | 0 | 38 |
| Example 2 | | | | |
| Comparative | Comparison 3 | 20 | 0 | 2 |
| Example 3 | | | | |
| Comparative | Comparison 4 | 1780 | 0 | 37 |
| Example 4 | | | | |

As clear from Table 2 above, it has been found that the polishing compositions of Examples can allow the polishing removal rate of a material having a silicon-silicon bond to be enhanced and are also excellent in step height reduction ability on a polishing object, as compared with the polishing compositions of Comparative Examples.

The present application is based on Japanese Patent Application No 2025-044834 filed on Mar. 19, 2025, the disclosure of which is herein incorporated by reference in its entirety.

1. A polishing composition comprising
(A) a water-soluble polymer containing a lactam structure, and
(B) an amine compound, wherein
the (B) component has 7 or more and less than 17 carbon atoms, and
a content mass ratio of the (B) component to the (A) component is more than 1.

2. The polishing composition according to claim 1, wherein the (A) component is at least one selected from the group consisting of polyvinylpyrrolidone, polyvinycaprolactam, polyvinylvalerolactam, polyvinyllaurolactam, and polyvinylpiperidone.

3. The polishing composition according to claim 1, wherein the (B) component has a cyclic structure.

4. The polishing composition according to claim 3, wherein the (B) component is at least one of 1,4-bis(3-aminopropyl)piperazine (BAPP) and 1,8-diazabicyclo[5.4.0]undeca-7-ene (DBU).

5. The polishing composition according to claim 1, further comprising a dispersing medium.

6. The polishing composition according to claim 1, wherein a pH is 8 or more and 12 or less.

7. The polishing composition according to claim 1, wherein a content of an abrasive grain based on a total mass of the polishing composition is less than 0.5% by mass.

8. The polishing composition according to claim 1, for use in the polishing of a polishing object containing a material having a silicon-silicon bond.

9. The polishing composition according to claim 8, wherein the material having a silicon-silicon bond is amorphous silicon.

10. The polishing composition according to claim 8, wherein the polishing object further contains a material having a silicon-nitrogen bond.

11. A polishing method comprising polishing a material having a silicon-silicon bond, in which the material is embedded on a substrate having a depressed portion so as to cover the depressed portion, with the polishing composition according to claim 1.
